(19) United States
(12) Patent Application Publication
(10) Pub. No.: US 2024/0010125 A1
(43) Pub. Date: Jan. 11, 2024

(54) APPARATUS, METHOD, AND COMPUTER-READABLE STORAGE MEDIUM FOR DETERMINING CONNECTION OF TRAILER

(71) Applicant: SEGI R&D LIMITED, Incheon (KR)

(72) Inventors: In Yong LEE, Nonsan-si (KR); Duck Hee LEE, Incheon (KR)

(21) Appl. No.: 17/857,329

(22) Filed: Jul. 5, 2022

(51) Int. Cl. B60Q 11/00; B60Q 1/00; B60Q 1/30; G01R 31/66; G01R 31/00

(52) U.S. Cl. CPC B60Q 11/00; B60Q 1/0094; B60Q 1/305; G01R 31/66; G01R 31/006

(57) ABSTRACT

An apparatus for determining connection of a trailer includes: a voltage applying unit configured to apply a test voltage to a lamp, provided in a trailer, through a driving voltage supply line according to a lamp check signal, the driving voltage supply line being a line through which a driving voltage is supplied from a vehicle to the lamp; and a control unit configured to determine whether the vehicle and the trailer are connected to each other, based on a voltage applied to a connection detection resistor, provided in the voltage applying unit, by the applied test voltage. A magnitude of current, flowing to the lamp when the test voltage is applied, is smaller than a magnitude of current flowing to the lamp when the driving voltage is applied.

### BACKGROUND

### 1. Field

The present disclosure relates to an apparatus, a method, and a computer-readable storage medium for determining connection of a trailer.

### 2. Description of Related Art

In general, a trailer refers to an apparatus connected to a rear end of a vehicle such as a tractor. A plurality of lamps, such as a turn signal lamp and the like, should be mounted on such a trailer due to regulations. When a trailer is connected to a vehicle, a lamp mounted on the trailer receives driving power from the vehicle to operate.

Accordingly, by determining whether a lamp mounted on a trailer is operating, an identification may be made as to whether the trailer is connected to a vehicle.

To determine whether the vehicle and the trailer are connected to each other, a driver may step on a brake pedal to illuminate a brake lamp or may manipulate a turn signal lever to operate a turn signal lamp. Alternatively, a lamp control device of the trailer may operate the lamp. However, in this case, other drivers may be disturbed and a large amount of power may be consumed.

### PRIOR ART DOCUMENTS

[Patent Document]
Korean Patent Publication No. 10-2015-0080339 (entitled “METHOD FOR AWARING A TRAILER USE FOR A TRACTOR,” published on Jul. 9, 2015)

### SUMMARY

An aspect of the present disclosure is to provide an apparatus, a method, and a computer-readable storage medium for determining connection of a trailer, which do not disturb other drivers and may reduce power consumption and determine whether a vehicle and a trailer are connected to each other even when a portion of a plurality of lamps fail.

According to an aspect of the present disclosure, an apparatus for determining connection of a trailer includes: a voltage applying unit configured to apply a test voltage to a lamp, provided in a trailer, through a driving voltage supply line according to a lamp check signal, the driving voltage supply line being a line through which a driving voltage is supplied from a vehicle to the lamp; and a control unit configured to determine whether the vehicle and the trailer are connected to each other, based on a voltage applied to a connection detection resistor, provided in the voltage applying unit, by the applied test voltage. A magnitude of current, flowing to the lamp when the test voltage is applied, is smaller than a magnitude of current flowing to the lamp when the driving voltage is applied.

According to another aspect of the present disclosure, a method for determining connection of a trailer includes: a first operation in which a control unit applies a lamp check signal; a second operation in which a voltage applying unit applies a test voltage to a lamp, provided in a trailer, through a driving voltage supply line according to the applied lamp check signal, the driving voltage supply line being a line through which a driving voltage is supplied from a vehicle to the lamp; and a third operation in which the control unit determines whether the vehicle and the trailer are connected to each other, based on a voltage applied to a connection detection resistor, provided in the voltage applying unit, by the applied test voltage. A magnitude of current, flowing to the lamp when the test voltage is applied, is smaller than a magnitude of current, flowing to the lamp when the driving voltage is applied.

According to another aspect of the present disclosure, a computer-readable storage medium, having a program allowing the method to be executed by a computer, is provided.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram of an apparatus for determining connection of a trailer according to an exemplary embodiment in the present disclosure.

FIG. 2 is a flowchart illustrating a method for determining connection of a trailer according to an exemplary embodiment in the present disclosure.

FIG. 3 is a block diagram of a computer device, capable of entirely or partially implementing an apparatus for determining connection of a trailer according to an exemplary embodiment in the present disclosure.

### DETAILED DESCRIPTION

Hereinafter, exemplary embodiments in the present disclosure will be described more completely, with reference to the accompanying drawings. The exemplary embodiments may, however, be modified in many different forms and should not be construed as being limited to the embodiments set forth herein. In the drawings, shapes and dimensions may be exaggerated for clarity, and the same reference numerals will be used throughout to designate the same elements.

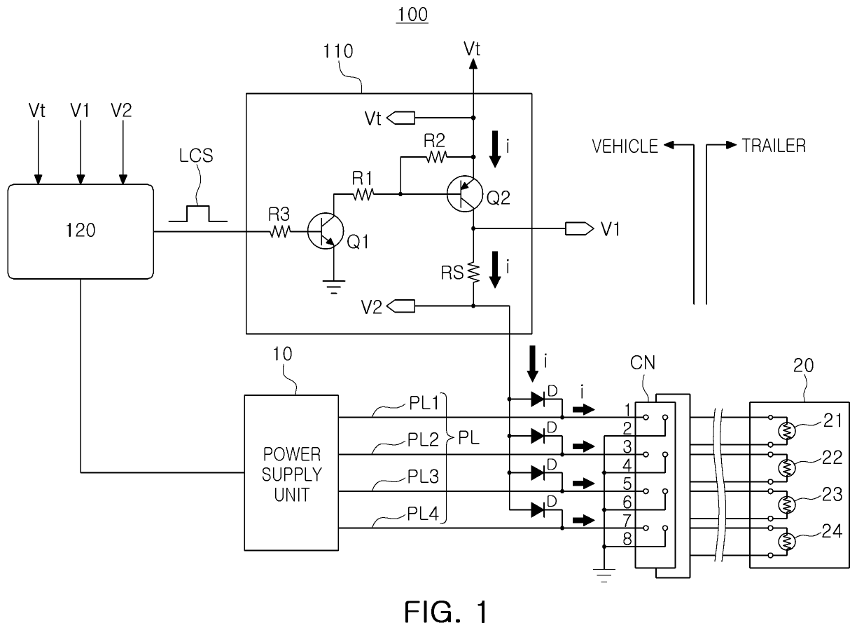

FIG. 1 is a block diagram of an apparatus 100 for determining connection of a trailer according to an exemplary embodiment in the present disclosure.

As illustrated in FIG. 1, the apparatus 100 for determining connection of a trailer may include a voltage applying unit 110 and a control unit 120.

Specifically, the voltage applying unit 110 may apply a test voltage Vt to a lamp 20 through a driving voltage supply line PL when a lamp check signal LCS is applied from the control unit 120.

The above-mentioned driving voltage supply line PL may be a line through which a driving voltage, supplied from the power supply unit 10, is supplied to the lamp 20 provided in the trailer.

In addition, the above-mentioned lamp check signal LCS may be a voltage in the form of a pulse having a predetermined turn-on time. The turn-on time may be adjusted to allow the test voltage Vt to be applied for only a short turn-on time.

Alternatively, the lamp check signal LCS may have a form in which a turn-on time and a turn-off time are repeated. When the turn-on time includes a plurality of turn-on times, a control unit to be described later may determine connection of the trailer for each of the plurality of turn-on times.

According to an exemplary embodiment, a magnitude of current, flowing to a lamp when a test voltage is applied, may be set to be smaller than a magnitude of current flowing to the lamp when a driving voltage is applied. Accordingly, the lamp may be turned off or may be turned on for only a short amount of time with a low brightness, at which it is difficult to be recognized even when the lamp is turned on, to determine whether a vehicle and a trailer are connected to each other, without disturbing other drivers. In addition, it may be advantageous in reducing power consumption when determining whether the vehicle and the trailer are connected to each other. The current, flowing to the lamp when the test voltage is applied, may be minute current having a magnitude of, for example, several microamperes (uA) to several milliamperes (mA). However, it should be noted that the above-mentioned specific values of the current are provided for better understanding of the present disclosure, and exemplary embodiments are not limited to the above-described specific values.

The lamp 20 provided in the trailer may include a single lamp or a plurality of lamps 21 to 24, and may be, for example, a brake lamp, a left signal lamp, a right signal lamp, and/or the like. When the lamp 20 includes the plurality of lamps 21 to 24, each of the plurality of lamps 21 to 24 may receive a driving voltage from the power supply unit 10 through separate driving voltage supply lines PL1 to PL4. In FIG. 1, the lamp is illustrated as including the four lamps 21 to 24, but it should be noted that the number of lamps may vary depending on needs of those skilled in the art. A reference CN in FIG. 1 represents connector.

As illustrated in FIG. 1, the voltage applying unit 110 may include an NPN transistor Q1, having a first base connected to the control unit 120 through a base resistor R3 and receiving the lamp check signal LCS from the control unit 120, a first emitter connected to ground, and a first collector to which one end of a first division resistor is connected, and a PNP transistor Q2, having a second base to which the other end of the first division resistor R1 is connected, a second emitter to which the test voltage Vt is applied, and a second collector to which one end of a connection detection resistor Rs is connected, in which a second division resistor is connected between the other end of the first division resistor R1 and the second emitter. The other end of the connection detection resistor R2 may be connected to the driving voltage supply line PL. As necessary, the voltage applying unit 110 may further include a diode D for preventing reverse current.

When the driving voltage supply line PL includes a plurality of driving voltage supply lines PL1 to PL4, the other end of the connection detection resistor R2 may be connected to each of the plurality of driving voltage supply lines PL1 to PL4.

In the above-described present disclosure, the transistor has been described as an example, but it will be appreciated that various devices, such as a FET, may be used as long as they may implement switching functions.

Hereinafter, detailed operations of the voltage applying unit 11 will be described.

When the lamp check signal LCS is output to the NPN transistor Q1, the NPN transistor Q1 may be turned on.

Next, the test voltage Vt may be divided by the first division resistor R1 and the second division resistor R2, and the PNP transistor Q2 may be turned on by a voltage across the second division resistor R2.

Then, current “i” generated by the test voltage Vt may flow toward the lamp 20, and voltage drop may occur due to the connection detection resistor Rs. In this case, voltage drop may also occur between the second emitter and the second collector of the PNP transistor Q2.

As will be described later, the control unit 120 may determine whether the vehicle and the trailer are connected to each other, based on a voltage applied to the connection detection resistor Rs.

The control unit 120 may apply a lamp check signal LCS to the voltage applying unit 110. Then, the control unit 120 may determine whether the vehicle and the trailer are connected to each other, based on the voltage applied to the connection detection resistor Rs by the test voltage Vt applied by the voltage applying unit 110.

In this case, the control unit 120 may determine whether the vehicle and the trailer are connected to each other, based on a combination of the magnitude of the test voltage Vt, the magnitude of a first voltage V1 on one end of the connection detection resistor Rs, and the magnitude of a second voltage V2 on the other end of the connection detection resistor Rs. Specifically, the control unit 120 may determine that

the vehicle and the trailer are connected to each other, when at least one of a difference between the magnitude of the test voltage Vt and the magnitude of the first voltage V1, a difference between the magnitude of the test voltage Vt and the magnitude of the second voltage V2, and a difference between the magnitude of the first voltage V1 and the magnitude of a second voltage V2 is greater than or equal to a respective predetermined value.

It should be noted that the above-mentioned respective predetermined value may be set to an appropriate value depending on needs of those skilled in the art, and is not limited to specific numerical values in the present disclosure.

As described above, according to an exemplary embodiment, the magnitude of the current, flowing to the lamp when the test voltage is applied, may be set to be smaller than the magnitude of the current flowing to the lamp when the driving voltage is applied, so that the lamp may be turned off or may be turned on for only a short amount of time with a low brightness, at which it is difficult to be recognized even when the lamp is turned on, to determine whether the vehicle and the trailer are connected to each other, without disturbing other drivers.

In addition, according to an exemplary embodiment, the magnitude of the current, flowing to the lamp when the test voltage is applied, may be set to be smaller than the magnitude of the current flowing to the lamp when the driving voltage is applied, so that power consumption may be reduced, as compared with the case in which a driver actually steps on a brake to light a brake lamp or manipulates a turn signal to operate a turn signal lamp to determine whether a vehicle and a trailer are connected to each other.

In addition, according to an exemplary embodiment, when a plurality of lamps are provided, a test voltage may be applied to each of the plurality of lamps to determine whether the vehicle and the trailer are connected to each other, thereby determining whether the vehicle and the trailer are connected to each other, even when some of the plurality of lamps fail.

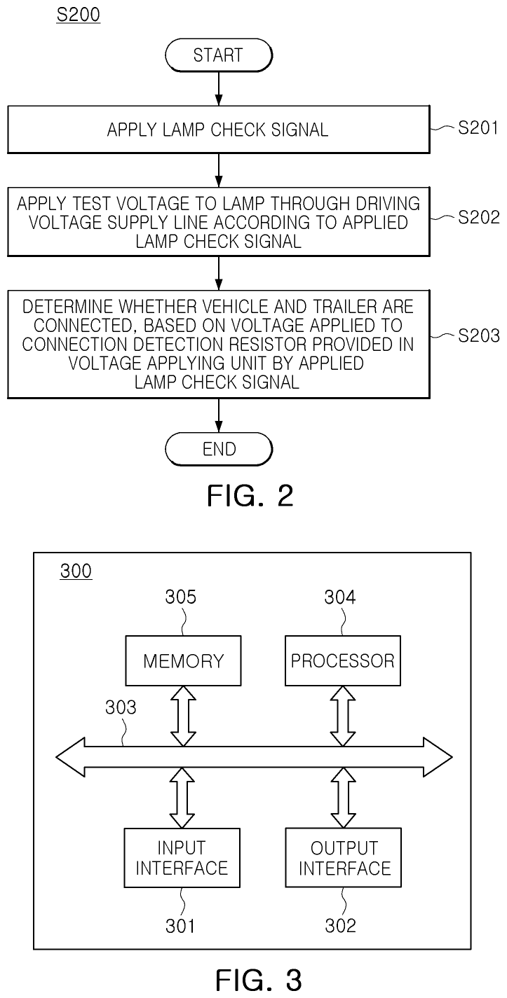

FIG. 2 is a flowchart illustrating a method for determining connection of a trailer according to an exemplary embodiment in the present disclosure.

Specifically, as illustrated in FIG. 2, a method 5200 for determining connection of a trailer according to an exemplary embodiment may start with operation 5201 in which the control unit 120 applies a lamp check signal LCS to the voltage applying unit 110. As described above, the lamp check signal LCS may be a voltage in the form of a pulse having a predetermined turn-on time.

In operation 5202, the voltage applying unit 110 may apply a test voltage Vt to the lamp 20 through the driving voltage supply line PL when the lamp check signal LCS is applied from the control unit 120.

As described above and illustrated in FIG. 1, the voltage applying unit 110 may include an NPN transistor Q1, having a first base connected to the control unit 120 through a base resistor R3 and receiving the lamp check signal LCS from the control unit 120, a first emitter connected to ground, and a first collector to which one end of a first division resistor is connected, and a PNP transistor Q2, having a second base to which the other end of the first division resistor R1 is connected, a second emitter to which the test voltage Vt is applied, and a second collector to which one end of a connection detection resistor Rs is connected, in which a second division resistor is connected between the other end of the first division resistor R1 and the second emitter.

In addition, as described above, the driving voltage supply line PL may be a line through which the driving voltage, supplied from the power supply unit 10, is supplied to the lamp provided in the trailer.

In addition, according to an exemplary embodiment, the magnitude of the current, flowing to the lamp when the test voltage is applied, may be set to be smaller than the magnitude of the current flowing to the lamp when the driving voltage is applied. Therefore, as described above, the lamp may be turned off or may be turned on for only a short amount of time with a low brightness, at which it is difficult to be recognized even when the lamp is turned on, to determine whether the vehicle and the trailer are connected to each other, without disturbing other drivers. In addition, as described above, it may be advantageous in reducing power consumption when determining whether the vehicle and the trailer are connected to each other. Finally, in operation 5605, the control unit 120 may

determines whether the vehicle and the trailer are connected to each other, based on the voltage applied to the connection detection resistor Rs by the test voltage Vt applied by the voltage applying unit 110.

For example, the control unit 120 may determine whether the vehicle and the trailer are connected to each other, based on a combination of the magnitude of the test voltage Vt, the magnitude of the first voltage V1 on one end of the connection detection resistor Rs, and the magnitude of the second voltage V2 on the other end of the connection detection resistor Rs.

As described above, specifically, the control unit 120 may determine that the vehicle and the trailer are connected to each other, when at least one of a difference between the magnitude of the test voltage Vt and the magnitude of the first voltage V1, a difference between the magnitude of the test voltage Vt and the magnitude of the second voltage V2, and a difference between the magnitude of the first voltage V1 and the magnitude of a second voltage V2 is greater than or equal to a respective predetermined value.

According to an exemplary embodiment, the magnitude of current, flowing to a lamp when a test voltage is applied, may be set to be smaller than the magnitude of current flowing to the lamp when a driving voltage is applied. Accordingly, the lamp may be turned off or may be turned on for only a short amount of time with a low brightness, at which it is difficult to be recognized even when the lamp is turned on, to determine whether a vehicle and a trailer are connected to each other, without disturbing other drivers.

In addition, according to an exemplary embodiment, the magnitude of the current, flowing to the lamp when the test voltage is applied, may be set to be smaller than the magnitude of the current flowing to the lamp when the driving voltage is applied, so that power consumption may be reduced, as compared with the case in which a driver actually steps on a brake to illuminate a brake lamp or manipulate a turn signal to operate a turn signal lamp to determine whether a vehicle and a trailer are connected to each other.

In addition, according to an exemplary embodiment, when a plurality of lamps are provided, a test voltage may be applied to each of the plurality of lamps to determine whether the vehicle and the trailer are connected to each other, thereby determining whether the vehicle and the trailer are connected to each other, even when some of the plurality of lamps fail.

FIG. 3 is a block diagram of a computer device, capable of entirely or partially implementing an apparatus 100 for determining connection of a trailer according to an exemplary embodiment in the present disclosure, and may be applied to the control unit 120 illustrated in FIG. 1.

As illustrated in FIG. 3, the computer device 100 may include an input interface 301, an output interface 302, a processor 304, and a memory 305. The input interface 301, the output interface 302, the processor 304, and the memory 305 may be connected to each other via a system bus 303.

In an exemplary embodiment, the memory 305 may be used to store a program, an instruction, or a code, and the processor 304 may execute the program, the instruction, or the code stored in the memory 305 and may control the input interface 301 to receive a signal and control the output interface 302 to transmit a signal. The memory 305 may include a read-only memory (ROM) and a random access memory (RAM), and may provide an instruction and data to the processor 304.

In an exemplary embodiment, it should be understood that the processor 304 may be a central processing unit (CPU), and the processor 304 may further be another general-purpose processor, a digital signal processor (DSP), an application-specific integrated circuit (ASIC), a field-programmable gate array (FPGA) or another programmable logical device, a discrete gate or transistor logical device, a discrete hardware component, or the like. The general-purpose processor may be a microprocessor, or may be any processor according to the related art, or the like.

In an implementation process, the method performed by each device of FIG. 1 may be achieved by an integrated logic circuit of hardware or instructions in the form of software in the processor 304. The content of the method disclosed in conjunction with the exemplary embodiments may be directly implemented and executed by a hardware processor, or may be executed and completed by a combination of hardware and software modules in the processor. The software module may be disposed in a storage medium such as a random access memory, a flash memory, a read-only memory, a programmable read-only memory, an electrically erasable programmable memory, a register, or the like. The storage medium may be disposed in the memory 305, and the processor 304 may read information in the memory 640 and may be combined with hardware to implement the content of the above-described method. Detailed descriptions will be omitted to avoid repetition.

Detection of connection of a trailer may be significantly important in determining conditions for optimal driving of a vehicle. The connection of the trailer may be detected and used to control fuel efficiency or energy efficiency, to control an output of an engine, to set autonomous driving, to control a parking warning, and the like.

As described above, according to exemplary embodiments, a magnitude of current, flowing to a lamp when a test voltage is applied, may be set to be smaller than a magnitude of current flowing to the lamp when a driving voltage is applied, so that the lamp may be turned off or may be turned on for only a short amount of time with a low brightness, at which it is difficult to be recognized even when the lamp is turned on, to determine whether a vehicle and a trailer are connected to each other, without disturbing other drivers.

In addition, according to an exemplary embodiment, a magnitude of current, flowing to a lamp when a test voltage is applied, may be set to be smaller than a magnitude of current flowing to the lamp when a driving voltage is applied, so that power consumption may be reduced, as compared with the case in which a driver actually steps on a brake to illuminate a brake lamp or manipulates a turn signal to operate a turn signal lamp to determine whether a vehicle and a trailer are connected to each other.

In addition, according to an exemplary embodiment, when a plurality of lamps are provided, a test voltage may be applied to each of the plurality of lamps to determine whether the vehicle and the trailer are connected to each other, thereby determining whether the vehicle and the trailer are connected to each other, even when some of the plurality of lamps fail.

While example embodiments have been shown and described above, it will be apparent to those skilled in the art that modifications and variations could be made without departing from the scope of the present invention as defined by the appended claims.

What is claimed is:

1. An apparatus for determining connection of a trailer, the apparatus comprising:
a voltage applying unit configured to apply a test voltage to a lamp, provided in a trailer, through a driving voltage supply line according to a lamp check signal, the driving voltage supply line being a line through which a driving voltage is supplied from a vehicle to the lamp; and
a control unit configured to determine whether the vehicle and the trailer are connected to each other, based on a voltage applied to a connection detection resistor, provided in the voltage applying unit, by the applied test voltage,
wherein
a magnitude of current, flowing to the lamp when the test voltage is applied, is smaller than a magnitude of current flowing to the lamp when the driving voltage is applied.

2. The apparatus of claim 1, wherein
the voltage applying unit comprises:
an NPN transistor, having a first base connected to the control unit through a base resistor and receiving the lamp check signal from the control unit, a first emitter connected to ground, and a first collector to which one end of a first division resistor is connected; and
a PNP transistor, having a second base to which the other end of the first division resistor is connected, a second emitter to which the test voltage is applied, and a second collector to which one end of a connection detection resistor is connected, in which a second division resistor is connected between the other end of the first division resistor and the second emitter, and
the other end of the connection detection resistor is connected to the driving voltage supply line.

3. The apparatus of claim 2, wherein
the control unit determines whether the vehicle and the trailer are connected to each other, based on a combination of a magnitude of the test voltage, a magnitude of a first voltage 15 on one end of the connection detection resistor and a magnitude of a second voltage on the other end of the connection detection resistor.

4. The apparatus of claim 3, wherein
the control unit determines that the vehicle and the trailer are connected to each other, when at least one of a difference between the magnitude of the test voltage and the magnitude of the first voltage, a difference between the magnitude of the test voltage and the magnitude of the second voltage, and a difference between the magnitude of the first voltage and a magnitude of a second voltage is greater than or equal to a respective predetermined value.

5. The apparatus of claim 4, wherein
the lamp includes at least one lamp,
when the lamp includes two or more lamps, each of the two or more lamps receives the driving voltage through separate driving voltage supply lines, and
the other end of the connection detection resistor is connected to each of the separate driving voltage supply lines.

6. The apparatus of claim 1, wherein
the lamp check signal is a voltage in a form of a pulse having a predetermined turn-on time.

7. A method for determining connection of a trailer, the method comprising:
a first operation in which a control unit applies a lamp check signal;
a second operation in which a voltage applying unit applies a test voltage to a lamp, provided in a trailer, through a driving voltage supply line according to the applied lamp check signal, the driving voltage supply line being a line through which a driving voltage is supplied from a vehicle to the lamp; and
a third operation in which the control unit determines whether the vehicle and the trailer are connected to each other, based on a voltage applied to a connection detection resistor, provided in the voltage applying unit, by the applied test voltage,
wherein a magnitude of current, flowing to the lamp when the test voltage is applied, is smaller than a magnitude of current, flowing to the lamp when the driving voltage is applied.

8. The method of claim 7, wherein
the voltage applying unit comprises:
an NPN transistor, having a first base connected to the control unit through a base resistor and receiving the lamp check signal from the control unit, a first emitter connected to ground, and a first collector to which one end of a first division resistor is connected; and
a PNP transistor, having a second base to which the other end of the first division resistor is connected, a second emitter to which the test voltage is applied, and a second collector to which one end of a connection detection resistor is connected, in which a second division resistor is connected between the other end of the first division resistor and the second emitter, and
the other end of the connection detection resistor is connected to the driving voltage supply line.

9. The method of claim 8, wherein
in the third operation, a determination is made as to whether the vehicle and the trailer are connected to each other, based on a combination of a magnitude of the test voltage, a magnitude of a first voltage on one end of the connection detection resistor and a magnitude of a second voltage on the other end of the connection detection resistor.

10. The method of claim 9, wherein
in the third operation, it is determined that the vehicle and the trailer are connected to each other, when at least one of a difference between the magnitude of the test voltage and the magnitude of the first voltage, a difference between the magnitude of the test voltage and the magnitude of the second voltage, and a difference between the magnitude of the first voltage and a magnitude of a second voltage is greater than or equal to a respective predetermined value.

11. The method of claim 10, wherein
the lamp includes at least one lamp,
when the lamp includes two or more lamps, each of the two or more lamps receives the driving voltage through separate driving voltage supply lines, and
the other end of the connection detection resistor is connected to each of the separate driving voltage supply lines.

12. The method of claim 7, wherein
the lamp check signal is a voltage in a form of a pulse having a predetermined turn-on time.

13. A computer-readable storage medium having a program allowing the method, set forth in claim 7, to be executed by a computer.
